(19) United States
(12) Patent Application Publication
(10) Pub. No.: US 2020/0141990 A1
(43) Pub. Date: May 7, 2020

(54) Electrical Extraction of Piezoelectric Constants

(71) Applicant: United Arab Emirates University, Al Ain (AE)

(72) Inventor: Mahmoud F. Y. Al Ahmad, Al Ain (AE)

(21) Appl. No.: 16/674,515

(22) Filed: Nov. 5, 2019

Related U.S. Application Data
(60) Provisional application No. 62/755,770, filed on Nov. 5, 2018.

(51) Int. Cl. G01R 27/26

(52) U.S. Cl. CPC G01R 27/2617

(57) ABSTRACT

Activity of piezoelectric material dimension and electrical properties can be changed with an applied stress. These variations are translated to a change in capacitance of the structure. Use of capacitance-voltage measurements for the extraction of double piezoelectric thin film material deposited at the two faces of a flexible steel sheet is described. Piezoelectric thin film materials are deposited using RF sputtering techniques. Gamry analyzer references 3000 is used to collect the capacitance-voltage measurements from both layers. A developed algorithm extracts directly the piezoelectric coefficients knowing film thickness, applied voltage, and capacitance ratio. The capacitance ratio is the ratio between the capacitances of the film when the applied field in antiparallel and parallel to the polling field direction, respectively. Piezoelectric bulk ceramic is used for calibration and validation by comparing the result with the reported values from literature. Extracted values using the current approach match well values extracted by existing methods.

### CROSS-REFERENCE TO RELATED APPLICATION

This application claims the benefit of U.S. Provisional Application No. 62/755,770, filed on Nov. 5, 2018, which is incorporated herein by reference in its entirety.

### BACKGROUND

Piezoelectric materials own special characteristics and properties that make them an excellent candidate to be utilized in advanced sensing fields. Such materials have been integrated and incorporated within highly adaptive smart structures. Flexible piezoelectric thin films have been implemented in biomedical applications due to their advantages of having highly piezoelectric constants, lightweight, slim, and biocompatible properties. Lead zirconate titanate (PZT) is a common piezoelectric material that is used for piezoelectric sensors and actuators. On the other hand, the monolithic integrated PZT wavers or patches, including ceramic materials, have poor fatigue resistance and are very fragile. That limits their ability to adapt to curved surfaces and makes them vulnerable to breakage accidentally through the bonding and handling procedures. This, in turn, affects the sensitivity of the sensor or actuator devices. The thin film technology finds further applications in such complicated conditions and curved surfaces. To overcome these issues, PZT was deposited on flexible sheets. The piezoelectric thin films on flexible sheets respond to nanoscale biomechanical vibrations caused by acoustic waves and tiny movements on corrugated surfaces of internal organs. Furthermore, it is used for developing self-powered energy harvesters, as well as sensitive nano-sensors for diagnostic systems. Flexible sheets of PZT material are naturally tough and pliable unlike the traditional piezoelectric patches. Xu et al. have developed a piezoelectric tape that is composed of patterned packed PZT elements sandwiched between two flexible metallic films. The PZT elements can have various distribution densities and shapes. They can be grouped or addressed individually. This phased array piezoelectric tape has good conformability to curved surfaces which makes it suitable to be used in different mechanical structures.

An apparent knowledge of material characteristics, including the piezoelectric coefficients and the electromechanical coupling factors is necessary for using the piezoelectric thin films in micromechanical systems (MMES). Uskokovie et al. has Compared the resulted piezoelectric coefficient values with other materials in other researches. Jackson et al. compared between capacitance-voltage (CV) method, laser doppler vibrometer (LDV), Berlincourt, and piezoelectric force microscopy (PFM) method to find piezoelectric properties of aluminum nitride (AlN). They concluded that LDV and PFM are the most accurate. In contrast, they reported that the CV method easiest and quickest method to use. Hemert et al. elaborated on the capacitance-voltage measurements and proposed a bias independent capacitance model as an alternative. They extracted from their proposed model d₃₃ and k, then verified the results at various biased electrodes thicknesses. They have used bulk acoustic wave (BAW) resonator model as a bias dependent capacitance model for piezoelectric capacitors. Using this model, the piezoelectric coefficient d₃₃ and dielectric constant were extracted from CV recording for three different layers thicknesses. On the other hand Hemert et al. criticized the CV method in other research as they concluded that the permittivity is not constant, so the piezoelectric parameters needs further information to be determined by the CV measurement such as the resonance measurements. Zhang et al. took AlN properties and studied the coefficients of AlN films by microscopy measurement and finite element method; they criticized the capacitance method due to the effect of interfacial capacitance between PZT films and electrodes as well as its low precision.

In previous research, Al Ahmad et al. have presented a new method of measuring piezoelectric thin film's vertical extension by utilizing the capacitance-voltage (CV) approach. This approach has received attention and several studies had commented and elaborated on its cons and pros. As a summary, many researchers have considered the reported CV method to be easiest and provides quick results; as it does not require sample preparations as in other competing methods, which makes it cheaper. In this paper, the piezoelectric coefficients have been extracted by a new algorithm using the CV method and applied to a proposed piezoelectric structure. The development of advanced piezoelectric structures that incorporate two piezoelectric layers sandwiching a flexible metallic sheet call for further optimization and enhancement of the current existing characterization methods. For an example, such structure can be inserted in a microfluidic channel to compare between two different pressures, each applied to a piezoelectric layer. The difference between the pressures (AP) can be translated into capacitance change (AC) in each layer.

### BRIEF DESCRIPTION OF THE DRAWINGS

FIGS. 1A, 1B, and 1C shows illustration of piezoelectric materials response to applied electrical field: unbiased disk (FIG. 1A), anti-parallel (FIG. 1B), and parallel biasing schemes (FIG. 1C).

FIG. 2 shows illustration of double piezoelectric layers (PZE1 and PZE2) sandwiching a metallic sheet (Shim) with polling directions (↓P).

FIG. 3 shows XRD measurements of the fabricated PZT layer.

FIG. 4 shows measured CV of bulk sample.

FIG. 5 shows capacitance versus frequency measurements for unbiased (at zero volts), anti (at +3 volt) and parallel biasing (at −3 volt).

FIG. 6 shows simultaneous CV measurements of the two piezoelectric layers.

FIG. 7 shows extracted piezoelectric voltage constants using (equation 12).

FIG. 8 shows polarization curve for the deposited film above steel sheet.

FIGS. 9A and 9B show extracted normalized capacitance ratio (Cr) values versus normalized applied electric field (Eₙ) voltage along with their corresponding fitting curves: bulk sample used for calibration (FIG. 9A) and thin film under study (FIG. 9B).

### DETAILED DESCRIPTION

This work investigates the use of CV characteristics to extract the piezoelectric voltage constants utilizing the change in capacitance. A new proposed structure composed of two piezoelectric layers is proposed and analyzed using the developed method. The following sections illustrate the approach of characterizing the piezoelectric material, the properties of the prepared sample, and the calibration technique to optimize the characterization algorithm.

### Capacitive-Voltage Approach

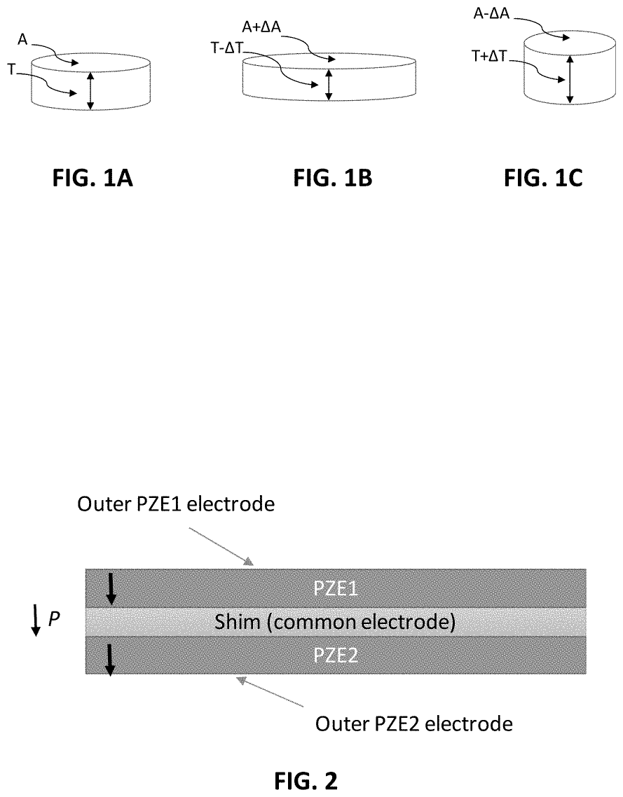

When a piezoelectric material is sandwiched between two electrodes subjected to either mechanical or electrical strains, its geometrical dimensions and dielectric constant will change according to the direction and magnitude of the applied field. FIG. 1A illustrates a circular disk of a piezoelectric material without applying any type of field. When this disk is driven by applied electrical field with the direction opposite to the polling direction, the thickness decreases and the area increases simultaneously as depicted in FIG. 1B, resulting an increase in capacitance. On the other hand, if the applied electric field is aligned with the polling direction, the thickness increases and the area decreases simultaneously as depicted in FIG. 1C, resulting the decrease in capacitance. Mathematically, a parallel plate capacitance can be expressed as per equation (1), as follow:

C=εA/T (1)

where: ε, A and T are the dielectric constant, area, and thickness of piezoelectric layer sandwiched between the common and the outer electrode. The application of dc field opposite to the polled field will result in the contraction of the layer thickness and expansion in the area, hence the capacitance is expressed as per equation (2):

C_{↓↑}=ε(A+ΔA)(T−ΔT)⁻¹ (2)

where ΔA and ΔT are the variation in area and thickness, respectively. Meanwhile, the application of dc field parallel to the polled field will result in the contraction of the layer area and expansion in the thickness, hence the capacitance is expressed as per equation (3):

C_{↑↑}=ε(A−ΔA)(T+ΔT)⁻¹ (3)

Dividing (2) over (3), yields:

Cᵣ(T−ΔT)(T+ΔT)⁻¹=(A+ΔA)(A−ΔA)⁻¹ (4)

Where Cᵣ=C_{↓↑}/C_{↑↑}. Equation (4) connects the change in capacitance ratio with the change in dimension due to the piezoelectric effect. With the help of (1+x)ⁿ=1+nx, yields:

Cᵣ(1−2ΔT/T)=(1+2ΔA/A) (5)

Equation (5) correlate the changes in capacitance ratio to both changes in thickness and area.

It is worth to mention that the deposition process of both layers may end up with different thicknesses and dielectric constants, as they deposited sequentially. To overcome such discrepancies, the variation in areas, thicknesses, and dielectric constants is expressed in terms of applied electric field, rather than the applied voltage. By this, the geometrical variations and change in dielectric constants will be normalized. The variation in thickness and area in terms of applied electric field (E) can be expressed as follow:

±ΔT/T=±d₃₃E (6)

±ΔA/A=±2d₃₁E+(d₃₁E)² (7)

Where d₃₃ and d₃₁ are the longitudinal and transversal piezoelectric voltage constants, respectively. As revealed from (6), the variation in thickness exhibits a linear relationship with the applied field, and from (7) the variation in area exhibits a quadratic relationship with the applied field. Substituting (6) and (7) into (5), produces:

Cᵣ−2Cᵣd₃₃E=1+4d₃₁E+2(d₃₁E)² (8)

Rearrange (8) for d₃₁, assuming d₃₃=2d₃₁ yields:

2E²d₃₁²+(4ECᵣ+4E)d₃₁+(1−Cᵣ)=0 (9)

Solving equation (9) for d₃₁, yields:

d₃₁=(−(Cᵣ+1)±{square root over (Cᵣ²+2.5Cᵣ+0.5))}E⁻¹ (10)

Equation (10) states that there are two possible solutions, nevertheless, if the materials exhibit no piezoelectric effect, Cᵣ is equal to 1 and d₃₁ is equal to zero. Hence the solution should read:

d₃₁=(−(Cᵣ+1)+{square root over (Cᵣ²+2.5Cᵣ+0.5))}E⁻¹ (11)

The significant of (11) that it can solve for d₃₁ without any required knowledge and information about the change in dielectric constant or any other variations. The only needed parameter is the thickness of the sputtered thin film. Hence for a given piezoelectric film, after the polling process, the capacitances are recorded corresponding to specific voltage value with negative and positive polarities. Then the electric field (E) and capacitance ratio (CO are computed. It is worth to mention that the assumed condition d₃₃=2d₃₁, can be replaced by more general one d₃₃=xd₃₁, where x can assume its values between 1 and 3. Furthermore, almost 95% of the published literature in PZT based piezoelectric materials has reported numerically values for d₃₃ and d₃₁; accordingly they can be approximated so that d₃₃=2d₃₁. Indeed, for the PZT based materials, the domain structure of the grains has a strong influence on this ratio (d₃₃/d₃₁).

### Sample Preparation

To demonstrate the current approach, a thin piezoelectric film is deposited on both sides of steel sheet using the sputtering technique. The deposition conditions are listed in Table 1. The film post annealing process was done at 700° C. for one hour. The thickness of the employed steel flexible sheet is of 50 μm, and the thickness of the deposited piezoelectric layers on both steel sides was measured to be 2.41 μm. FIG. 2 illustrates the stack composed of thin metallic steel sheet that coated from both sides with noble materials PLT/Pt/Ti as a seeding layer for the deposition of the piezoelectric thin film materials layers on both faces of the steel. As illustrated in FIG. 2, the shim layer is a flexible steel sheet which acts as a common electrode. Furthermore, both outer surfaces of PZE1 and PZE2 are coated with Al metallization to form electrical contacts. The films polling has been conducted at room temperature with the application of 250 kV/cm was applied for 20 minutes. The CV measurements are conducted between the metallic shim and the outer electrical electrodes.

As illustrated in FIG. 2, both layers have been polled in the same direction, hence for identically applied voltage polarities applied across them, their thicknesses will either both increases or decreases simultaneously. Meanwhile, if the applied voltages polarities are opposite to each other, one layer will increase in thickness and the other layer thickness will decrease.

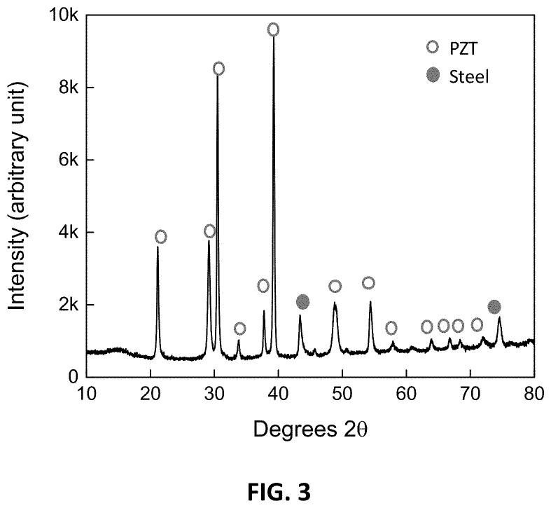

To assess the efficiency of the fabrication process, the XRD measurements have been conducted for the steel flexible sheet before PZT deposition (blank) and for the flexible sheet with a PZT deposited over steel (coated). FIG. 3 represents the XRD measurements, the filled circle represents the diffraction peaks of steel flexible sheet, and the open circles represent the diffraction peaks of the PZT deposition layer on the flexible steel sheet. Clearly, that existence of multi peaks stimulates that the distribution of the peaks along the angle of orientation reveals that the PZT deposition quality is high and the sample does not have disordered materials.

TABLE 1
PZT thin film deposition conditions

| | Ti | Pt | PLT | PZT |
|---|---|---|---|---|
| Deposition temp [° C.] | 500 | 500 | 650 | 700 |
| Sputtering Pressure | 0.8 | 0.5 | 0.5 | 0.5 |
| [Pa] | | | | |
| RF power [W] | 80 | 100 | 150 | 90 |
| Ar/O₂ [sccm] | 20/0 | 20/0 | 19.5/0.5 | 19.5/0.5 |
| Deposition time [min] | 6 | 8 | 15 | 300 |

### Calibration Method

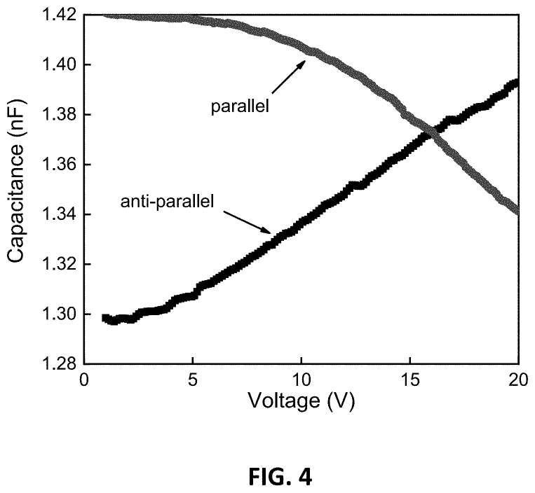

To further calibrate the proposed method, PZT unclamped bulk ceramic with thickness 0.24 mm has been utilized. The CV measurements are depicted in FIG. 4. The measured d₃₁ using Berlincourt meter is of 250 μm per volt of this unclamped sample. The extracted d₃₁ piezoelectric voltage constant using (11) yields 190 μm per volt. The current method is corrected by multiplying (11) with a factor (4/3), to correct the discrepancy between measured and extracted values; hence equation (11) is modified as per (12). Equation (12) incorporates the correction factor for calibration.

d₃₁=(4/3)(−(Cᵣ+1)+{square root over (Cᵣ²+2.5Cᵣ+0.5))}E⁻¹ (12)

### Results and Discussion

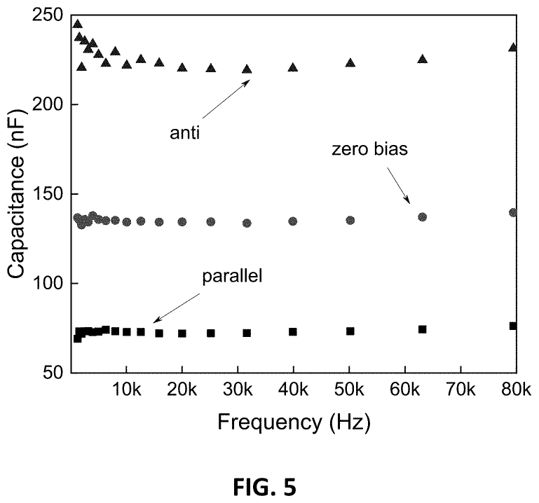

The electrical measurement was taken using the Gamry 3000 reference equipment. Capacitances versus frequency measurements (at zero bias) were conducted to determine the frequency range and its self-resonance frequency. The capacitance shows a smooth response over the frequency as displayed by FIG. 5. The measurements were taken along frequency variations in the range of 1-80 kHz. A dc voltage was applied to both layers for capacitance versus frequency at +3 volt dc bias (anti-polarization), and at −3 volt dc voltage bias (parallel to polarization).

FIG. 5 shows that when the applied voltage is anti-parallel to the poling direction of PZT material, the values of the measured capacitance increases with the frequency as it reaches around 230 nF. On the other hand, applying voltage parallel to the poling direction decreases the values of the measured capacitance slightly with the frequency and reaches around 75 nF. While in the zero biasing case, the capacitance measurements nearly stayed constant around the value 135 nF along the range of the frequency. As anticipated, the applied voltage in either parallel or opposite to poling direction will cause a change in the dimension which is pronounced by the capacitance measurements.

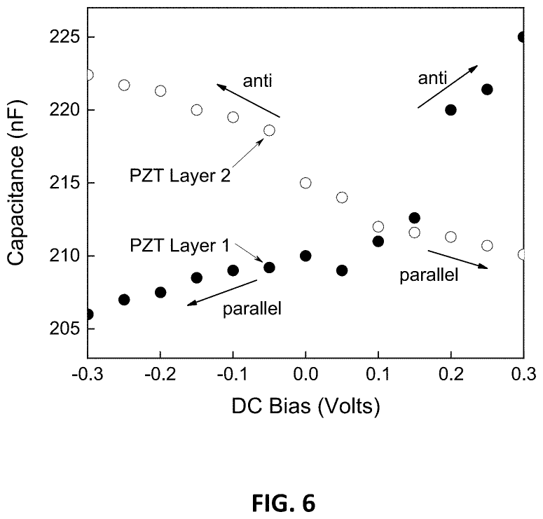

The two layers have been polled in opposite directions. FIG. 6 shows the two piezoelectric capacitance voltage responses when the applied voltage swept from −0.3 to +0.3 volts. For layer 1, the capacitance increase for the positive applied field as it is driven opposite to the polling field direction, meanwhile it decreases for the negative values as it is driven parallel to the to the polling field direction. On contrary, for layer 2, the capacitance increases for negative applied field as it is driven parallel to the polling field direction, meanwhile it decreases for positive values as it is driven opposite to the to the polling field direction.

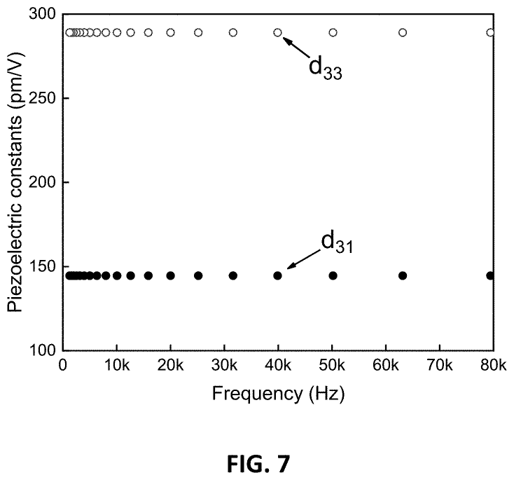

With the help of (12) and the data presented in FIG. 5, the extracted d₃₁ and d₃₃ piezoelectric voltage constants have been estimated and depicted in FIG. 7. The applied electric field is of 1.25 volt per μm. The constants exhibit a smooth behavior over the wide frequency range. At a frequency of 40 kHz, d₃₃ and d₃₁ constants read 284 and 142 μm per volt, respectively. These values are comparable with reported values in the literature for same thin film thickness.

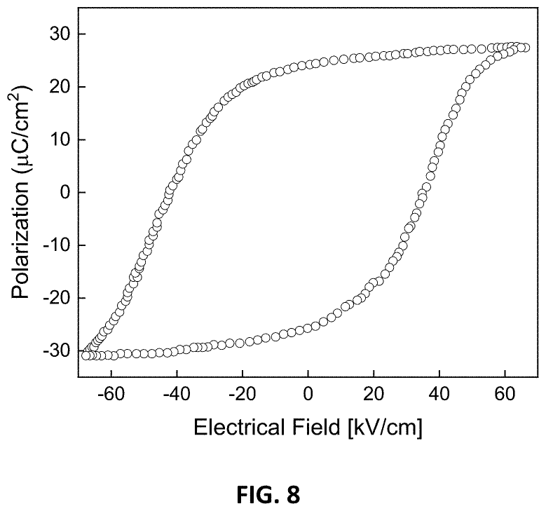

Equation (12) along with CV measurements presented in FIG. 6 have been used to extract the piezoelectric constants of both layer 1 and layer 2 of the stack shown in FIG. 2. The estimated mean values of values for d₃₁ of layer 1 and 2 are 125 and 130 μm per volt, respectively. Furthermore, the variation in the capacitance incorporating piezoelectric materials due to the applied voltage can be generated either by the dielectric constant voltage dependency and/or from the expansion/contraction in the dimensions of the poled material. FIG. 8 revealed that the change in the polarization due to the change in electric field is equal to 1.6 C/cm². Hence the equivalent capacitance change from this change in polarization is of 0.6 pF. Therefore, 1% of the measured capacitance change is due to dielectric constant voltage dependency while 99% of this change is referred to the variations of sample dimensions due to the piezoelectric effect. The piezoelectric constant (e31,f) is then estimated to be −3.8 C/m². The dielectric constant of the film is computed to be of 240 on average.

Direct extraction of d₃₃ and d₃₁ from Cr-E

It is also possible to extract simultaneously the d₃₁ and d₃₃ piezoelectric constants directly from (8). Equations (8) could be arranged to express the capacitance ratio (Cr) as a function of applied voltage (E), as per equation (13):

Cᵣ=(1+4d₃₁E+2(d₃₁E)²)(1−2d₃₃E)⁻¹ (13)

With the help of (1+x)ⁿ=1+nx, yields:

Cᵣ=(1+4d₃₁E+2(d₃₁E)²)(1+2d₃₃E) (14)

Equation (14) could be further simplified as follow:

Cᵣ=1+2(d₃₃+2d₃₁)E+2(4d₃₁d₃₃+d₃₁d₃₁)E²+4d₃₁²d₃₃E³ (15)

The last cubic term of (15) can be neglected, due its very small value; which yields:

Cᵣ=1+2(d₃₃+2d₃₁)E+2(4d₃₁d₃₃+d₃₁d₃₁)E² (16)

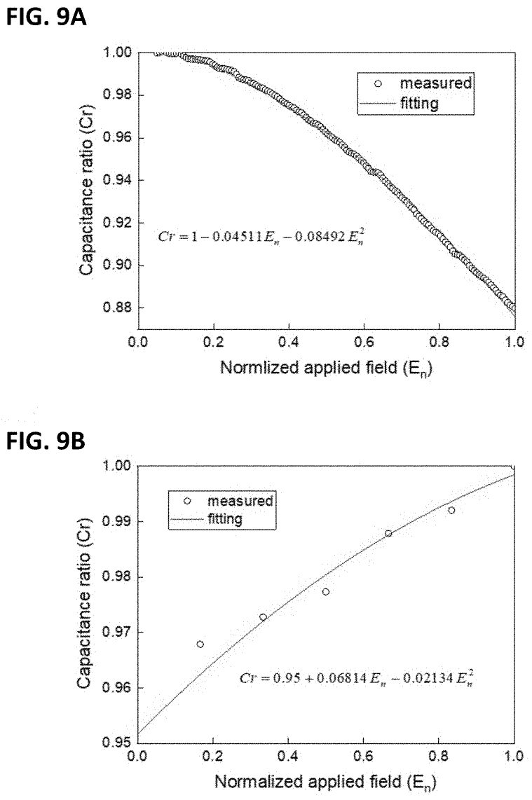

Equation (16) suggest that d₃₁ and d₃₃ can be extracted simultaneously by fitting the measured Cr values versus E; with the quadratic fitting. For calibration purposes, a piezoelectric bulk ceramic materials of thickness 0.150 mm with d₃₃ and d₃₁ of 430 and 230 μm per volts, respectively, has been utilized. Nevertheless, as both the calibration sample and sample under test have different thicknesses of more than three order of magnitudes; it is suggested to use the normalized applied electric field to count for this difference. FIGS. 9A and 9B display the measured capacitance ratio versus the normalized applied field for the bulk and thin film samples, respectively. The fitting equation of the extracted capacitance ratio versus the normalized applied electric field for the bulk sample is found to be:

Cᵣ=1−0.04511Eₙ−0.08492Eₙ² (17)

Comparing (17) with equation (16), the second and the third terms account for the piezoelectric effect. Hence:

2(d₃₃+2d₃₁)=−0.04511 (18)

2(4d₃₁d₃₃+d₃₁d₃₁)=−0.0849 (19)

Solving (18) and (19) simultaneously for d₃₃ and d₃₁ yields 0.0846 pC/N and 0.1666 pC/N, respectively. Hence for calibration the solution for (18) and (19) should be multiplied by a factor of 2700 to calibrate the method. Therefore the actual d₃₃ and d₃₁ reads 448 pC/N and 228 pC/N, respectively; i.e. d₃₃ is equal 1.96 times d₃₁ (approximately d₃₃≈2d₃₁). For the film understudy; the corresponding fitting equation is found to be:

Cᵣ=0.95+0.06814Eₙ−0.02134Eₙ² (20)

Solving (18) and (19) for (20), incorporating the calibration step yields d₃₃ and d₃₁ of 134 pC/N and 256 pC/N, respectively. The direct extraction using the Cr-E approach produces a maximum error of 5%.

Direct Extraction of d₃₃ and d₃₁ from Fr-E

Incorporating a piezoelectric material in a resonator structure that has a measurable resonance frequency, with the possibility to drive this resonator against and along polarization/polling directions, the resonance frequency is then can be written as:

$$f = \frac{1}{2 π \sqrt{LC}} \qquad ( 17 \text{-} 1 )$$

Where L is the effective inductor of the resonator, which will not change with driving the piezoelectric against or along the polling field. fr is the frequency ratio between the resonance frequency along the polarization over the resonance frequency measured when drive against the polling:

$${f}_{r} = \frac{1}{2 π \sqrt{{LC}_{p}}} / \frac{1}{2 π \sqrt{{LC}_{a}}} \qquad ( 18 \text{-} 1 )$$

### Yields:

$${f}_{r} = \sqrt{\frac{{C}_{a}}{{C}_{p}}} \qquad ( 19 \text{-} 1 )$$

i.e.,

fᵣ=\sqrt{Cᵣ} (20-1)

### Hence

$${f}_{r} = AT ( 1 + \frac{Δ A}{A} ) ( 1 + \frac{Δ T}{T} ) \qquad ( 21 )$$

### Therefore

$${f}_{rn} = ( 1 + \frac{Δ A}{A} ) ( 1 + \frac{Δ T}{T} ) \qquad ( 22 )$$

Which produces:

fᵣₙ=(1+2d₃₁E+(d₃₁E)²)(1+d₃₃E) (23)

And therefore

fₙ=1+(2d₃₁+d₃₃)E+(2d₃₁d₃₃+d₃₁²)E²+d₃₁²d₃₃E³ (24)

Thus by fitting the frn versus applied E with cubic equation, the coefficient d31 and d33 can be extracted.

### CONCLUSION

The characterization of piezoelectric constants relevant to a specific application will enhance their use. This work contributes to the development of an innovative methodology to determine the piezoelectric constants. The piezoelectric material should be incorporated as a capacitance dielectric materials. An electric applied field is then applied to drive the film parallel and anti-parallel to the polling field direction. This usually done by sweeping the voltage from negative to positive values. The variations in geometric dimensions and the corresponding dielectric constant of the materials due to the applied field will be reflected in the measured capacitance. The developed model requires only the pre-knowledge of the film thickness and automatically de-embed the change in dielectric constant due to the applied stress. The proposed method has been calibrated using unclamped bulk PZT ceramic and validated using conventional meters. The estimated and measured values are well corroborated with each other. The proposed technique does not require any sample heavy preparation steps, and provides a rapid response along with accurate estimation.

1. A device configured for direct extraction of d₃₃ and d₃₁ from Cr-E.

2. A device configured for direct extraction of d₃₃ and d₃₁ from fr-E.

3. A method for direct extraction of d₃₃ and d₃₁ from Cr-E.
